(19) United States
(12) Patent Application Publication
(10) Pub. No.: US 2025/0393205 A1
(43) Pub. Date: Dec. 25, 2025

(54) THREE-DIMENSIONAL MEMORY DEVICE AND METHOD OF FORMING THE SAME

(71) Applicant: MACRONIX International Co., Ltd., Hsinchu (TW)

(72) Inventors: Ching Yao Wang, Hsinchu City (TW); Guan-Ru Lee, Hsinchu City (TW)

(73) Assignee: MACRONIX International Co., Ltd., Hsinchu (TW)

(21) Appl. No.: 18/751,340

(22) Filed: Jun. 24, 2024

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

Provided is a three-dimensional (3D) memory device including: a dielectric substrate, a stack structure, and a protective layer. The stack structure is disposed on the dielectric substrate. The stack structure includes a plurality of dielectric layers and a plurality of conductive layers stacked alternately. The protective layer covers a top surface, a first side wall and a bottom surface of the uppermost conductive layer among the plurality of conductive layers. A material of the protective layer includes silicon nitride.

### BACKGROUND

### Technical Field

The present invention relates to a semiconductor device and a method of forming the same, and more particularly to a three-dimensional (3D) memory device and a method of forming the same.

### Description of Related Art

A non-volatile memory (such as a flash memory) is a memory widely used in personal computers and other electronic devices because it has an advantage that the stored data does not disappear after being powered off.

The 3D flash memory currently used in the industry includes a NOR flash memory and a NAND type flash memory. In addition, another type of 3D flash memory is an AND type flash memory, which can be applied to a multi-dimensional flash memory array with high integration and high area utilization, and has an advantage of fast operation speed. Therefore, the development of the 3D flash memory has gradually become the current trend.

### SUMMARY

The present invention provides a three-dimensional (3D) memory device that uses a protective structure to surround surfaces and a sidewall of the uppermost conductive layer to prevent the bridge issue, thereby improving the reliability of the device.

The invention provides a three-dimensional memory device including: a dielectric substrate, a stack structure and a protective layer. The stack structure is disposed on the dielectric substrate, wherein the stack structure includes a plurality of dielectric layers and a plurality of conductive layers stacked alternately. The protective layer continuously covers a top surface, a first sidewall and a bottom surface of the uppermost conductive layer among the plurality of conductive layers. A material of the protective layer includes silicon nitride (SiN).

In an embodiment of the present invention, the three-dimensional memory device further includes a buffer layer, wherein the buffer layer continuously covers a top surface, a first sidewall and a bottom surface of the conductive layer except the uppermost conductive layer among the plurality of conductive layers.

In an embodiment of the present invention, the buffer layer is further disposed on a portion of the top surface and a portion of the bottom surface of the uppermost conductive layer and is connected to the protective layer.

In an embodiment of the present invention, the three-dimensional memory device further includes a vertical channel pillar, wherein the vertical channel pillar penetrates through the stack structure and is adjacent to the first sidewall of the uppermost conductive layer, and wherein the protective layer contacts the vertical channel pillar.

In an embodiment of the present invention, the vertical channel pillar includes: a first source/drain pillar and a second source/drain pillar, penetrating the stack structure and extending into the dielectric substrate; a dielectric material, disposed between the first source/drain pillar and the second source/drain pillar to separate the first source/drain pillar and the second source/drain pillar; a channel layer, surrounding the dielectric material, the first source/drain pillar and the second source/drain pillar, wherein the channel layer is in contact with the first source/drain pillar and the second source/drain pillar; and a charge storage structure, surrounding the channel layer.

In an embodiment of the present invention, at least one of the first source/drain pillar and the second source/drain pillar is in contact with the protective layer.

In an embodiment of the present invention, the uppermost conductive layer is used as a dummy word line.

In one embodiment of the present invention, the three-dimensional memory device includes a 3D AND flash memory, a 3D NAND flash memory, a 3D NOR flash memory, or a combination thereof.

In an embodiment of the present invention, a thickness of the protective layer is between 10 Å and 100 Å.

In an embodiment of the present invention, a thickness of the buffer layer is smaller than a thickness of the protective layer.

The invention provides a method of forming a three-dimensional (3D) memory device comprising: forming a stack structure having a plurality of dielectric layers and a plurality of sacrificial layers alternately stacked on the dielectric substrate; performing a first etching process to form a first opening in the stack structure, wherein the first opening exposes a top surface of the dielectric layer below an uppermost sacrificial layer; performing a second etching process through the first opening to remove the uppermost sacrificial layer to form a first horizontal opening; forming a protective layer and a first conductive layer in the first horizontal opening, wherein the protective layer continuously covers a top surface, a first sidewall and a bottom surface of the first conductive layer, wherein a material of the protective layer includes silicon nitride (SiN), and wherein the first opening is adjacent to a second sidewall opposite to the first sidewall of the first conductive layer; and performing a gate replacement process to replace the plurality of sacrificial layers with a plurality of second conductive layers.

In an embodiment of the present invention, before forming the first opening, the method further includes forming a vertical channel pillar in the stack structure, wherein the vertical channel pillar is adjacent to the first sidewall of the first conductive layer, and the protective layer contacts the vertical channel pillar.

In an embodiment of the present invention, the vertical channel pillar includes: a first source/drain pillar and a second source/drain pillar, penetrating the stack structure and extending into the dielectric substrate; a dielectric material, disposed between the first source/drain pillar and the second source/drain pillar to separate the first source/drain pillar and the second source/drain pillar; a channel layer, surrounding the dielectric material, the first source/drain pillar and the second source/drain pillar, and wherein the channel layer is in contact with the first source/drain pillar and the second source/drain pillar; and a charge storage structure, surrounding the channel layer.

In an embodiment of the present invention, at least one of the first source/drain pillar and the second source/drain pillar is in contact with the protective layer.

In an embodiment of the present invention, the first conductive layer is used as a dummy word line.

In an embodiment of the present invention, performing the gate replacement process comprises: performing a third etching process through the first opening to form a second opening in the stack structure; performing a fourth etching process through the second opening to remove the sacrificial layer to form a second horizontal opening between the dielectric layers; and forming the second conductive layers and a buffer layer in the second horizontal opening.

In an embodiment of the present invention, after performing the fourth etching process, a sidewall of the protective layer is concave from a sidewall of the dielectric layer and the second sidewall of the first conductive layer to form a gap.

In an embodiment of the present invention, the buffer layer is filled in the gap.

In an embodiment of the present invention, a thickness of the protective layer is between 10 Å and 100 Å.

In an embodiment of the present invention, a thickness of the buffer layer is smaller than a thickness of the protective layer.

Based on the above, in the present invention, an additional protective layer with high dielectric is used to cover the surfaces and a sidewall of the uppermost conductive layer to effectively prevent the bridge issue between the source/drain pillar (or conductive plug) and the word line, thereby improving reliability of three-dimensional (3D) memory devices. Further, the forming steps of the barrier structure of the present invention are compatible with the fabrication of current 3D memory device, and can be applied to various 3D memory devices.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a 3D memory device according to an embodiment of the invention.

FIG. 2A, FIG. 3A, and FIG. 4A are schematic cross-sectional views illustrating a vertical channel pillar according to various embodiments of the invention.

FIG. 2B, FIG. 3B, and FIG. 4B are schematic plan views of FIG. 2A, FIG. 3A, and FIG. 4A, respectively.

FIG. 5 to FIG. 12 are schematic cross-sectional views of a manufacturing process of a 3D memory device according to an embodiment of the invention.

FIG. 13 is a partial enlarged view of an embodiment of FIG. 12.

FIG. 14 is a partial enlarged view of another embodiment of FIG. 12.

FIG. 15A, FIG. 15B, and FIG. 15C are respectively a schematic perspective view, a schematic plan view, and a schematic circuit diagram of a 3D AND flash memory according to an embodiment of the present invention.

### DESCRIPTION OF THE EMBODIMENTS

The invention is more blanketly described with reference to the figures of the present embodiments. However, the invention can also be implemented in various different forms, and is not limited to the embodiments in the present specification. The thicknesses of the layers and regions in the figures are enlarged for clarity. The same or similar reference numerals represent the same or similar devices and are not repeated in the following paragraphs.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

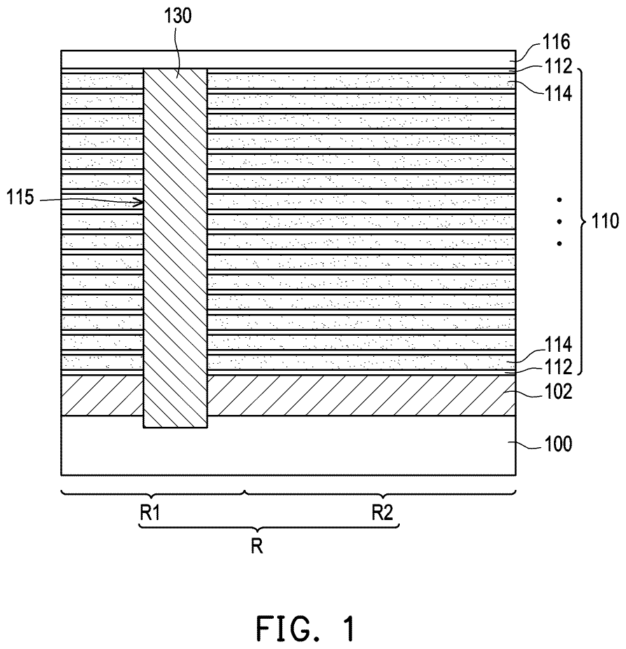

FIG. 1 is a schematic cross-sectional view of a 3D memory device according to an embodiment of the invention.

Referring to FIG. 1, in the embodiment of the present invention, a 3D memory device may include a dielectric substrate 100, a stop layer 102, a stack structure 110, a cap layer 116, and a vertical channel pillar 130. In some embodiments, the dielectric substrate 100 is, for example, a semiconductor substrate, a semiconductor compound substrate, or a semiconductor over insulator (SOI) substrate. The semiconductor is, for example, an atom of group IVA, such as silicon or germanium. The semiconductor compound is, for example, a semiconductor compound formed by atoms of group IVA, such as silicon carbide or germanium silicide, or a semiconductor compound formed by atoms of group IIIA and group VA, such as gallium arsenide. The dielectric dielectric substrate may be a dielectric layer formed on a silicon dielectric substrate, such as a silicon oxide layer. That is, there may be peripheral circuits under the dielectric substrate 100. In addition, the dielectric substrate 100 may include an array region R, the array region R may include a first region R1 and a second region R2. In an embodiment, the first region R1 may be a channel pillar region, and the second region R2 may be a slit region. That is, one or more slits may be adjacent to the channel pillar region R1.

The stop layer 102 may be formed on the dielectric substrate 100. In an embodiment, a material of the stop layer 102 includes a conductive material, such as polysilicon, III-V compound semiconductor, or a combination thereof. With an embodiment of the 3D memory device being a 3D NAND flash memory, the stop layer 102 may be used as a source line. With an embodiment of the 3D memory device being a 3D NOR flash memory, the stop layer 102 may be used as a dummy word line. Although the stop layer 102 illustrated in FIG. 1 is a single-layered structure, the present invention is not limited thereto. In other embodiments, the stop layer 102 may also be a multi-layered structure. The multilayer structure may include a plurality of dielectric layers (e.g., silicon oxide layers) and a plurality of conductive layers (e.g., polysilicon layers) stacked alternately.

The stack structure 110 may be formed on the stop layer 102, so that the stop layer 102 is disposed between the dielectric substrate 100 and the stack structure 110. In an embodiment, the stack structure 110 may include a plurality of dielectric layers 112 and a plurality of sacrificial layers 114 stacked alternately. In an embodiment, the dielectric layers 112 and the sacrificial layers 114 may be different dielectric materials or materials with different etching rates. For example, the dielectric layers 112 may be silicon oxide layers; and the sacrificial layers 114 may be silicon nitride layers, polysilicon layers or metal tungsten layers. The number of the dielectric layers 112 and the sacrificial layers 114 may be adjusted by the needs, the invention is not limited thereto.

The cap layer 116 may be formed on the stack structure 110 and the vertical channel pillar 130, so that the stack structure 110 is disposed between the stop layer 102 and the cap layer 116. In an embodiment, a material of the cap layer 116 includes a dielectric material, such as silicon oxide.

The vertical channel pillar 130 may be formed in the stack structure 110 and the stop layer 102 in the first region R1. As shown in FIG. 1, the vertical channel pillar 130 may penetrate through the stack structure 110, the stop layer 102, and partially extend into the dielectric substrate 100. It should be noted that when forming an opening 115 that may accommodate the vertical channel pillar 130, the stop layer 102 may be used not only as an etching stop layer, but also to prevent arcing effects generated during the plasma etching, thereby improving the reliability of the device. In this embodiment, the stop layer 102 may be regarded as a discharging layer, which is usually grounded to the silicon dielectric substrate to reduce the charge accumulated by the said plasma etching, thereby avoiding damage to the device. Therefore, during the high aspect ratio etching process, the stop layer 102 is usually grounded to the silicon dielectric substrate to avoid arc discharge.

Basically, according to different forms of the 3D memory device, the vertical channel pillar 130 may have different configurations, which are described in detail as follows.

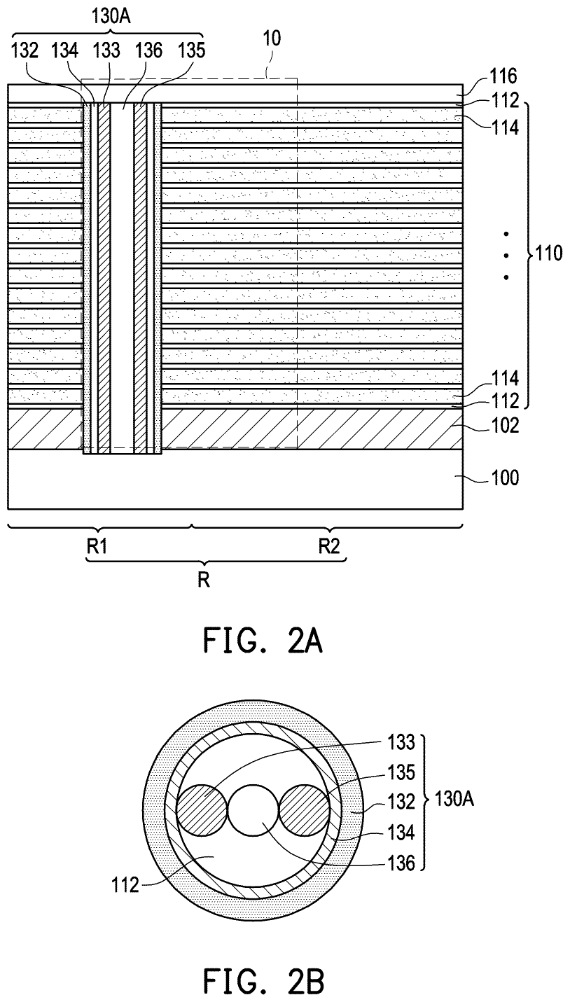

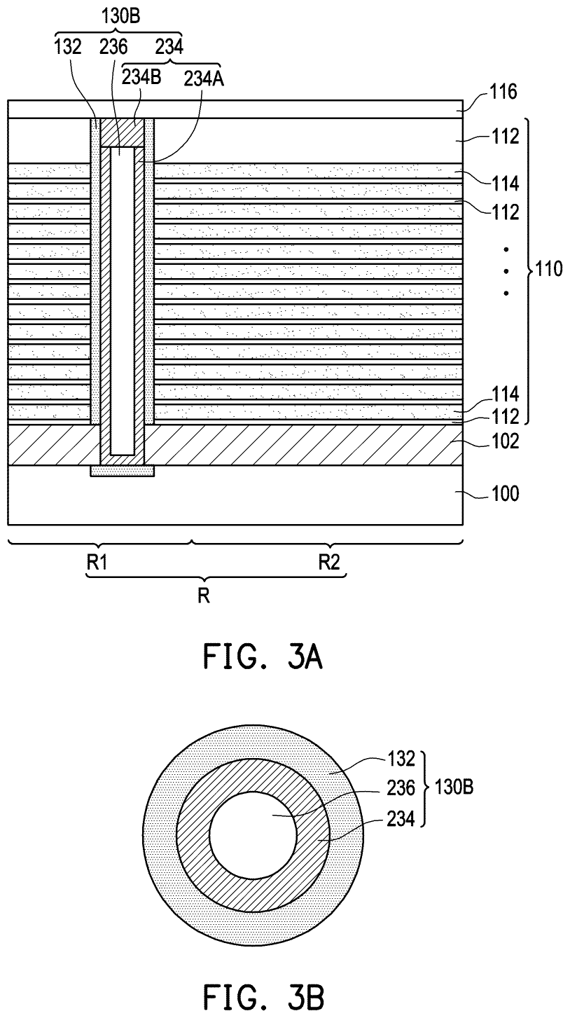

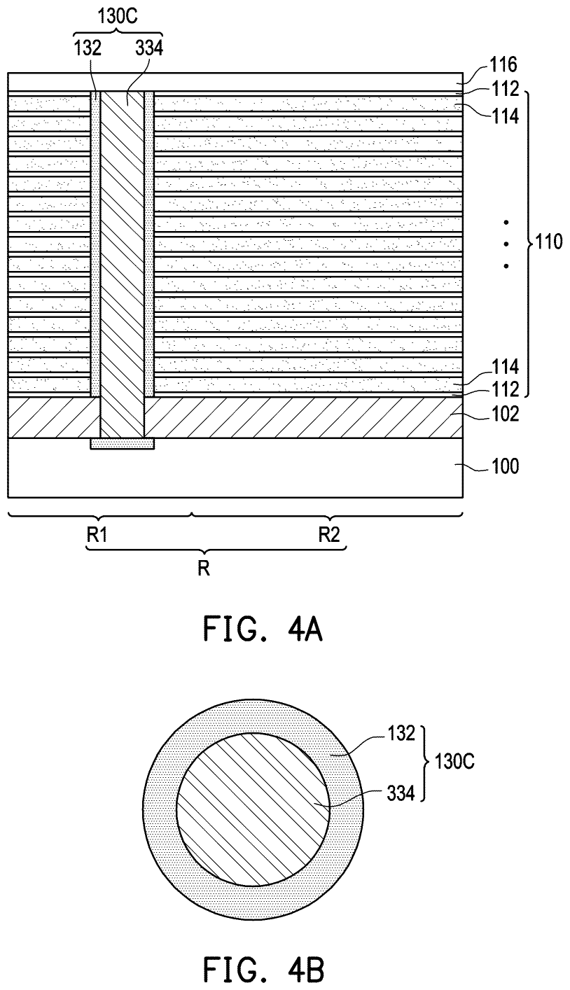

FIG. 2A, FIG. 3A, and FIG. 4A are schematic cross-sectional views illustrating a vertical channel pillar according to various embodiments of the invention. FIG. 2B, FIG. 3B, and FIG. 4B are schematic plan views of FIG. 2A, FIG. 3A, and FIG. 4A, respectively.

Referring to FIG. 2A and FIG. 2B, when the 3D memory device is a 3D AND flash memory, the vertical channel pillar 130A may include a charge storage structure 132, a channel layer 134, a dielectric pillar 136, a first source/drain (S/D) pillar 133, and a second S/D pillar 135. As shown in FIG. 2A, the first S/D pillar 133 and the second S/D pillar 135 may penetrate through the stack structure 110 and the stop layer 102, and partially extend into the dielectric substrate 100. In an embodiment, the first S/D pillar 133 and the second S/D pillar 135 may have the same conductive material, such as N-type doped (N+) polysilicon materials. The dielectric pillar 136 may disposed between the first S/D pillar 133 and the second S/D pillar 135 to separate the first S/D pillar 133 from the second S/D pillar 135. In addition, as shown in FIG. 2B, the channel layer 134 may laterally surround the dielectric pillar 136, the first S/D pillar 133 and the second S/D pillar 135. The first S/D pillar 133 and the second S/D pillar 135 physically contact a portion of the channel layer 134, respectively. The charge storage structure 132 may laterally surround the channel layer 134. In an embodiment, the charge storage structure 132 may be a composite layer of a tunneling layer, a charge storage layer and a block layer. The tunneling layer, the charge storage layer and the block layer may refer to oxide/nitride/oxide (ONO), respectively. In another embodiment, the tunneling layer may be a composite layer of oxide/nitride/oxide/(ONO), or other suitable materials. In alternative embodiments, the charge storage layer may be a composite layer of oxide/nitride/oxide (ONO), or other suitable materials. In other embodiments, the block layer may be a composite layer of oxide/nitride/oxide (ONO), or other suitable materials. The channel layer 134 may include a doped polysilicon layer or an undoped polysilicon layer. The dielectric pillar 136 may include silicon oxide, silicon nitride, silicon oxynitride, or a combination thereof.

Referring to FIG. 3A and FIG. 3B, when the 3D memory device is a first type of a 3D NAND flash memory, the vertical channel pillar 130B may include a charge storage structure 132, a channel structure 234, and a dielectric pillar 236. As shown in FIG. 3A, the dielectric pillar 236 may penetrate through the stack structure 110, and the stop layer 102. The channel structure 234 may include a liner 234A and a plug 234B. The liner 234A may cover the sidewall and the bottom surface of the dielectric pillar 236, and the plug 234B may seal the top surface of the dielectric pillar 236. In this case, the channel structure 234 may completely wrap all surfaces of the dielectric pillar 236. The charge storage structure 132 may be disposed between the channel structure 234 and the stack structure 110. The charge storage structure 132 between the channel structure 234 and the stop layer 102 is removed, so that the channel structure 234 directly contacts the stop layer 102. From the perspective of the plan view of FIG. 3B, the charge storage structure 132 may laterally surround the channel structure 234 and the dielectric pillar 236. The materials of the charge storage structure 132, the channel structure 234 and the dielectric pillar 236 are respectively the same as the charge storage structure 132, the channel layer 134 and dielectric pillar 136, and have been described in detail in the foregoing paragraphs, thus will not be repeated here.

Referring to FIG. 4A and FIG. 4B, when the 3D memory device is a second type of a 3D NAND flash memory, the vertical channel pillar 130C may include a charge storage structure 132 and a channel pillar 334. As shown in FIG. 4A, the channel pillar 334 may penetrate through the stack structure 110 and the stop layer 102. The charge storage structure 132 may be disposed between the channel pillar 334 and the stack structure 110. The charge storage structure 132 between the channel pillar 334 and the stop layer 102 is removed, so that the channel pillar 334 directly contacts the stop layer 102. From the perspective of the top view of FIG. 4B, the charge storage structure 132 may laterally surround the channel pillar 334. The materials of the charge storage structure 132 and the channel pillar 334 are respectively the same as the charge storage structure 132 and the channel layer 134, and have been described in detail in the foregoing paragraphs, thus will not be repeated here.

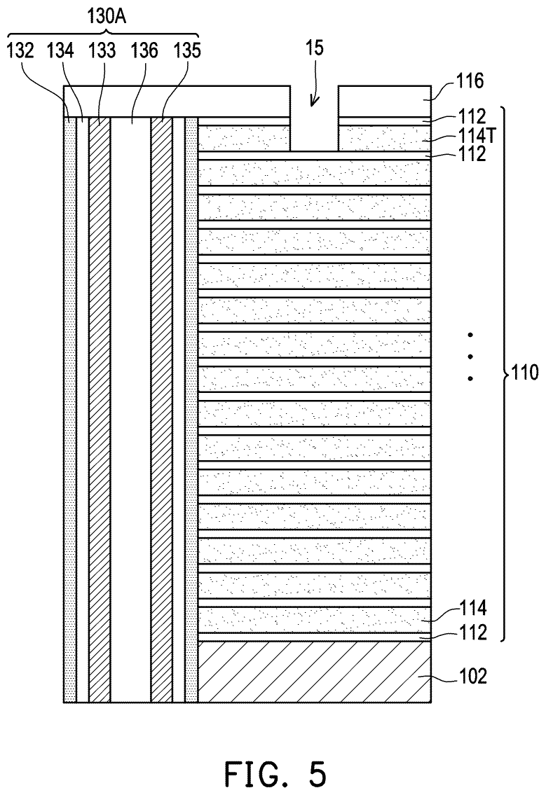

Referring back to FIG. 2A, after performing the vertical channel pillar 130A, a gate replacement process may be performed to replace the sacrificial layers 114 in the stack structure 110 with gate layers 154, as shown in FIG. 5 to FIG. 12.

FIG. 5 to FIG. 12 are schematic cross-sectional views of a manufacturing process of a 3D memory device according to an embodiment of the invention, wherein FIG. 5 to FIG. 12 are enlarged views of the region 10 illustrated in FIG. 2A.

First, as shown in FIG. 5, a first etching process is performed to form a first opening 15 in the stack structure 110 of the second area R2. The first opening 15 penetrates the cap layer 116 and the uppermost sacrificial layer 114T, and exposes a top surface of the dielectric layer 112 below the uppermost sacrificial layer 114T. In one embodiment, the first etching process may be an anisotropic etching process.

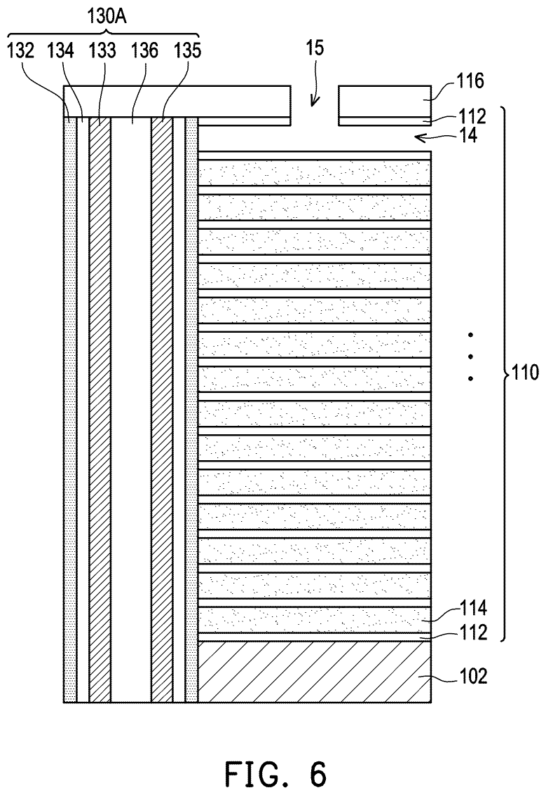

Next, referring to FIG. 6, a second etching process is performed through the first opening 15 to remove the uppermost sacrificial layer 114T to form a first horizontal opening 14 between the dielectric layers 112, wherein the first horizontal opening 14 laterally exposes a sidewall of the vertical channel pillar 130A. In other words, the first horizontal opening 14 is defined by the dielectric layer 112 and the vertical channel pillar 130A. In one embodiment, the said second etching process may be a wet etching process. For example, when the sacrificial layer is silicon nitride, the second etching process may use an etchant containing phosphoric acid and pour the etchant into the first opening 15 to remove the uppermost sacrificial layer 114T. Since the etchant has a high etching selectivity with respect to the uppermost sacrificial layer 114T, the uppermost sacrificial layer 114T may be completely removed, while the dielectric layers 112 are not removed or are only slightly removed.

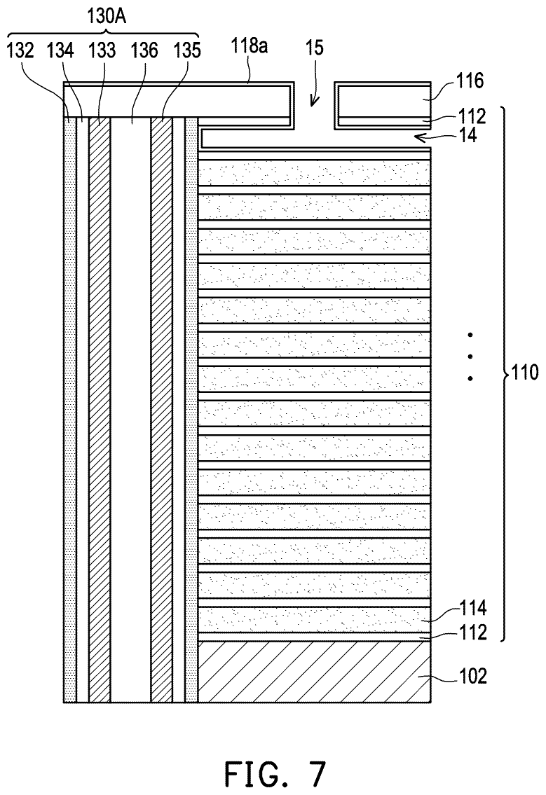

Referring to FIG. 6 and FIG. 7, a protection material layer 118a is formed in the first horizontal opening 14. Specifically, the protection material layer 118a conformally covers a top surface and a sidewall of the cap layer 116, a sidewall of the vertical channel pillar 130A, and the exposed surface and sidewall of the dielectric layer 112. In one embodiment, a material of the protection material layer 118a includes silicon nitride (SiN).

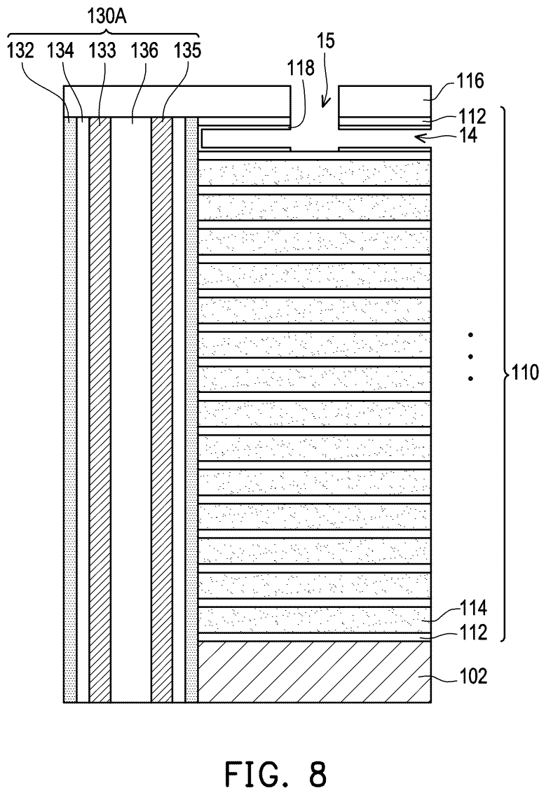

Referring to FIG. 7 and FIG. 8, an etching back process is performed to remove the protection material layer 118a on the top surface and sidewall of the cap layer 116, the sidewall of the dielectric layer 112, and a portion of the top surface of the dielectric layer, such that a protective layer 118 is formed in the first horizontal opening 14. In one embodiment, the etching back process may remove the protection material layer 118a on the top surface of the dielectric layer 112 aligned with the first opening 15 to expose the top surface of the dielectric layer 112. In the present embodiment, since the etching resistance of the protective material layer 118a (i.e. nitride) is different from the etching resistance of the capping layer 116 and the dielectric layer 112 (i.e. oxide), the excess protection material layer may be removed without damaging the surfaces of the cap layer 116 and the dielectric layer 112 during the etching back process.

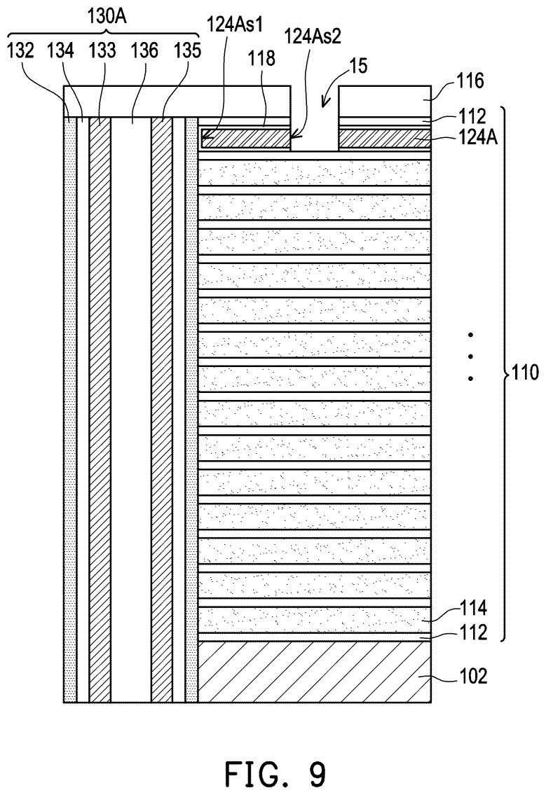

Referring to FIG. 8 and FIG. 9, a first conductive layer 124A is filled in the first horizontal opening 14. In some embodiments, a material of the first conductive layer 124A may include polysilicon, amorphous silicon, tungsten (W), cobalt (Co), aluminum (Al), tungsten silicide (WSiₓ), or cobalt silicide (CoSiₓ). In one embodiment, the material of first conductive layer 124A is polysilicon. The method for forming the first conductive layer 124A is, for example, to form a first conductive material layer on the stack structure 110 and in the first opening 15 and the first horizontal opening 14, and then the first conductive material layer is etched back to remove the first conductive material layer on the stack structure 110 and in the first opening 15.

As shown in FIG. 9, the protective layer 118 continuously covers a top surface, a first sidewall 124As1 and a bottom surface of the first conductive layer 124A. In one embodiment, a thickness of the protective layer 118 is between 10 Å and 100 Å. The thickness of the protective layer 118 may be adjusted according to the type of memory device. The first opening 15 exposes a second sidewall 124As2 opposite to the first sidewall 124As1 of the first conductive layer 124A. In other words, the first opening 15 is adjacent to the second sidewall 124As2 opposite to the first sidewall 124As1 of the first conductive layer 124A. In one embodiment, the first conductive layer 124A may be used as a dummy word line. In this embodiment, the uppermost conductive layer (i.e. the first conductive layer 124A) may serve as a dummy word line, and this dummy word line is not related to the operation of the device. The upper gate region may be controlled by applying a bias voltage to the dummy word line, thereby achieving the effect of suppressing channel leakage current.

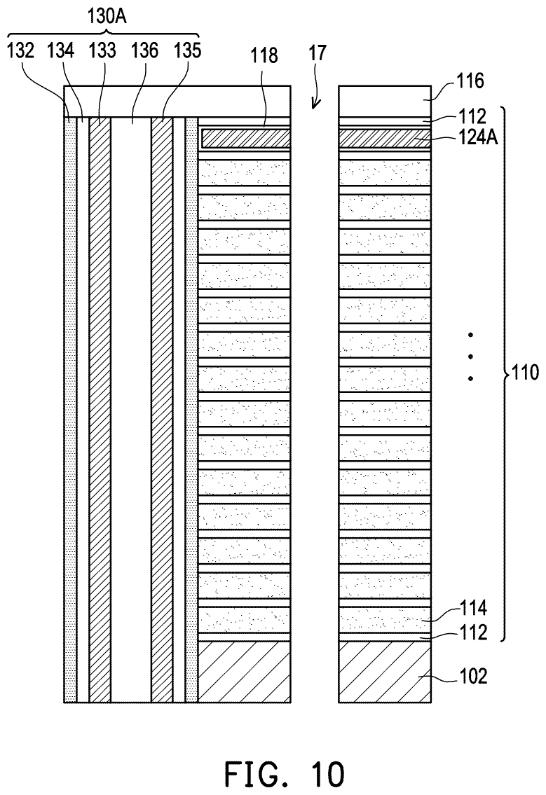

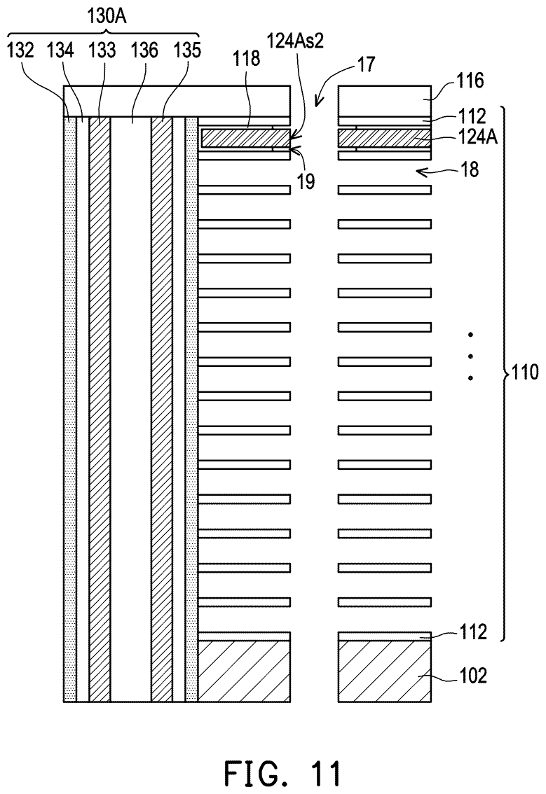

After the first conductive layer 124A is formed, a gate replacement process may be performed to replace the plurality of sacrificial layers 114 with the plurality of second conductive layers 124B (as shown in FIG. 12). Referring to FIGS. 9 and 10, a third etching process is performed through the first opening 15 to form a second opening 17 in the stack structure 110. The second opening 17 penetrates through the stack structure 110 and the stop layer 102. In the present embodiment, although the second opening 17 penetrates the stop layer 102 (as shown in FIG. 10), the present invention is not limited thereto. In other embodiments, the second opening 17 may expose a portion of the stop layer 102.

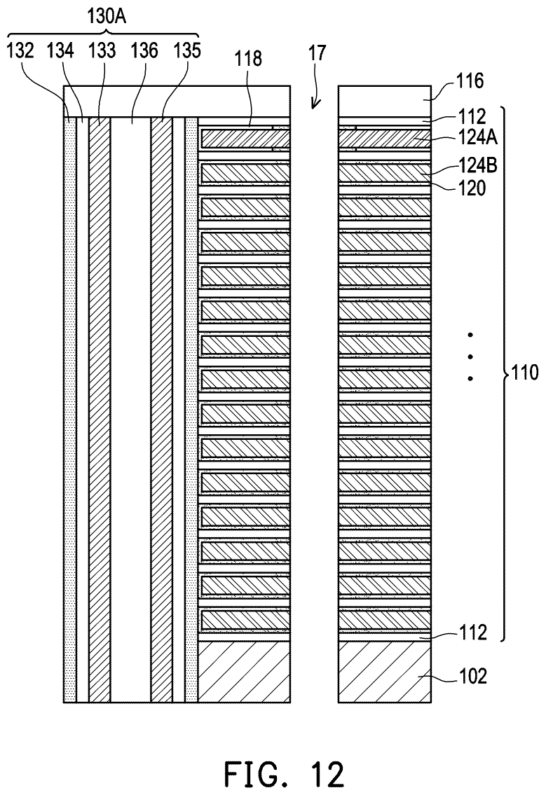

Referring to FIG. 10 and FIG. 11, a fourth etching process is performed through the second opening 17 to remove a plurality of sacrificial layers 114 to form a plurality of second horizontal openings 18 between the dielectric layers 112. The second horizontal opening 18 laterally exposes a sidewall of the vertical channel pillar 130A. In other words, the second horizontal opening 18 is defined by the dielectric layer 112 and the vertical channel pillar 130A. In one embodiment, the said fourth etching process may be a wet etching process. For example, when the sacrificial layers 114 are silicon nitride, the fourth etching process may use an etchant containing phosphoric acid and pour the etchant into the second opening 17 to remove the sacrificial layers 114. Since the etchant has a high etching selectivity with respect to the sacrificial layer 114, the sacrificial layer 114 may be completely removed, while the dielectric layer 112 is not removed or is only slightly removed.

In one embodiment, the fourth etching process also etches a portion of the protective layer 118. Specifically, after the fourth etching process is performed, the sidewall of the protective layer 118 is concave from the sidewall of the dielectric layer 112 and the second sidewall 124As2 of the first conductive layer 124A to form the gap 19. In other words, the gap 19 is defined by the dielectric layer 112, the protective layer 118 and the first conductive layer 124A.

Referring to FIG. 11 and FIG. 12, a buffer layer 120 and a second conductive layer 124B are sequentially formed in the second horizontal opening 18. Specifically, the buffer material layer and the second conductive material layer are sequentially filled in the second horizontal opening 18. The buffer material layer may conformally cover the surface of the structure shown in FIG. 11 and fill the second horizontal opening 18 and the gap 19. Specifically, the buffer material layer conformally covers a top surface and a sidewall of the cap layer 116, a sidewall of the vertical channel pillar 130A and the exposed surface and sidewall of the dielectric layer 112, and fills the gap 19. The second conductive material layer may fill the second horizontal opening 18 and extend laterally into the second opening 17. In one embodiment, a material of the buffer material layer may include a high dielectric constant material with a dielectric constant greater than 7, such as aluminum oxide (Al₂O₃), hafnium oxide (HfO₂), lanthanum oxide (La₂O₅), transition metal oxide, lanthanide oxides or a combination thereof. A material of the second conductive material layer may include polysilicon, amorphous silicon, tungsten (W), cobalt (Co), aluminum (Al), tungsten silicide (WSiₓ), or cobalt silicide (CoSiₓ). In one embodiment, the material of the second conductive material layer is the same as that of the first conductive material layer. In another embodiment, the material of the second conductive material layer is different from that of the first conductive material layer.

Then, an etching back process is performed to remove the buffer material layer and the second conductive material layer on the stack structure 110 and in the second opening 17 to form the buffer layer 120 and the second conductive layer 124B in the second horizontal opening 18 and to form a buffer layer 120 in the gap 19. In one embodiment, a thickness of the buffer layer 120 is 45 Å or less. In one embodiment, the thickness of the buffer layer 120 formed on the second conductive layer 124B is smaller than the thickness of the buffer layer 120 in the gap 19. More specifically, the thickness of the protective layer 118 and the buffer layer 120 covering the first conductive layer 124A is greater than the thickness of the buffer layer 120 covering the second conductive layer 124B.

Thereafter, subsequent related manufacturing processes (for example, further forming a slit filling structure in the second opening 17) may be performed to complete the production of the three-dimensional memory device.

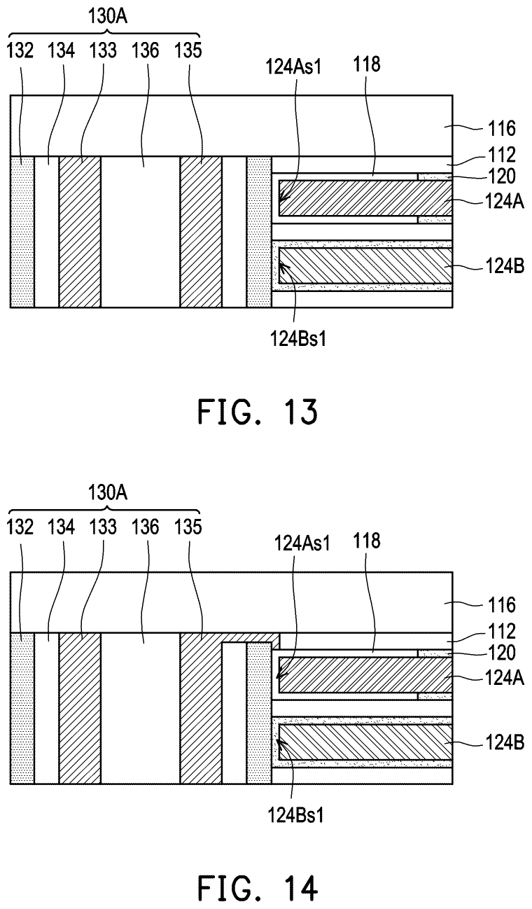

FIG. 13 is a partial enlarged view of an embodiment of FIG. 12.

Referring to FIG. 13, the 3D memory device includes a protective layer 118 disposed on the uppermost conductive layer (i.e. the first conductive layer 124A) among the plurality of conductive layers in the stack structure 110. The protective layer 118 continuously covers the top surface, the first sidewall 124As1 and the bottom surface of the first conductive layer 124A. The buffer layer 120 continuously covers the top surface, the first sidewall 124Bs1 and the bottom surface of the second conductive layer 124B. In the present embodiment, the buffer layer 120 is also disposed on a portion of the top surface and a portion of the bottom surface of the first conductive layer 124A and is connected to the protective layer 118. Specifically, the buffer layer 120 is disposed in gap 19 defined by the dielectric layer 112, the protective layer 118 and the first conductive layer 124A. In the present embodiment, the material of the protective layer 118 is different from the material of the buffer layer 120. The material of the protective layer 118 includes silicon nitride (SiN). The vertical channel pillar 130A penetrates through the stack structure 110 and is adjacent to the first sidewalls 124As1 and 124Bs1 of the first conductive layer 124A and the second conductive layer 124B, and the protective layer 118 contacts the charge storage structure 132 of the vertical channel pillar 130A.

FIG. 14 is a partial enlarged view of another embodiment of FIG. 12.

The 3D memory device of FIG. 14 is similar to the 3D memory device of FIG. 13, and the same or similar components are represented by the same or similar reference numbers, which will not be repeated here. The main difference between the above two lies in that the second source/drain pillar 135 of the three-dimensional memory device illustrated in FIG. 14 is in contact with the protective layer 118.

During the formation of the vertical channel pillar, the source/drain pillars (or conductive plug) may encounter shifting issues induces by non-uniform stress, and may etch outside of the original vertical channel pillar. Therefore, the source/drain pillar (or conductive plug) would be shifted to outside of the original vertical channel pillar and contact with the protective layer 118.

For the traditional method of manufacturing three-dimensional (3D) memory devices, if the source/drain pillar (or conductive plug) is shifted to outside of the original vertical channel pillar, the source/drain pillar (or conductive plug) would be in contact with the buffer layer. The memory cell is required to be controlled through the uppermost conductive layer (i.e. word line), so the thickness of the buffer layer is very thin. There will only exist a thin dielectric (such as Al₂O₃) buffer layer between the source/drain pillar (or conductive plug) and the uppermost conductive layer (i.e. word line). This buffer layer cannot withstand the operation voltage bias, thus easily result the bridge issue between the source/drain pillar (or conductive plug) and the word line due to the dielectric breakdown among the interface region. In other words, the buffer layer formed on the uppermost conductive layer (i.e. word line) is not sufficient to overcome the bridge issue.

However, in the present embodiment, a twice gate replacement process is adopted to replace the buffer layer on the uppermost conductive layer with a silicon nitride layer with high dielectric constant and protection function. More specifically, the thin silicon nitride layer (i.e. protective layer) is formed on the surface and the sidewall of the uppermost conductive layer. The dielectric constant of silicon nitride is much higher than that of oxide, so the protective layer helps to withstand the operation voltage bias between the shifted source/drain pillar (or conductive plug) and the word line, thereby preventing the bridge problem. In the present embodiment, the uppermost conductive layer may be used as a dummy word line, whose purpose is to control the gate to prevent leakage current.

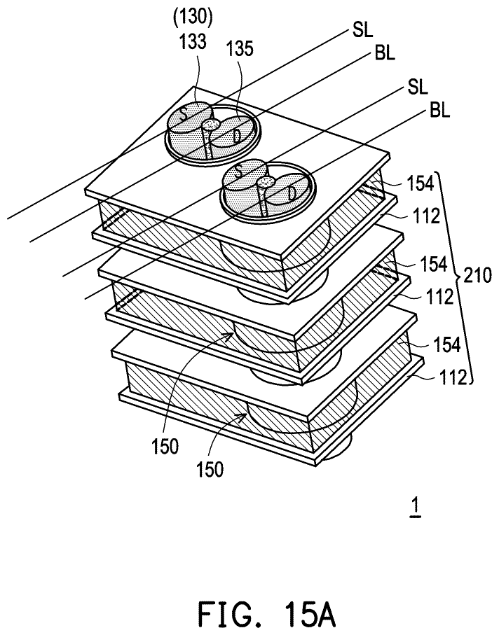

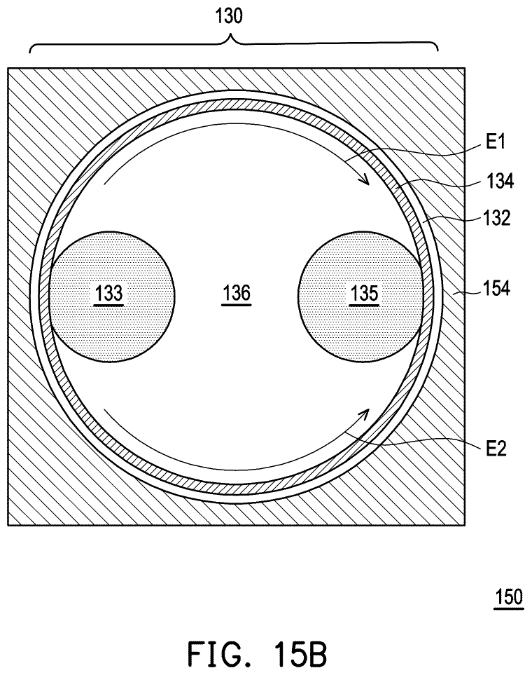

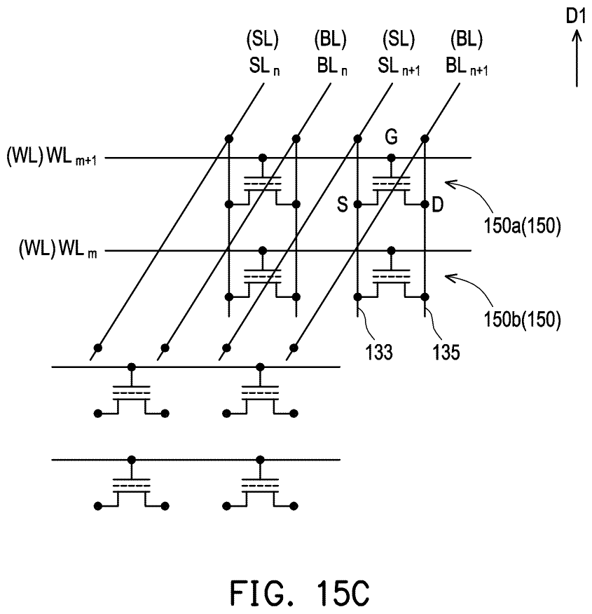

FIG. 15A, FIG. 15B, and FIG. 15C are respectively a schematic perspective view, a schematic plan view, and a schematic circuit diagram of a 3D AND flash memory 1 according to an embodiment of the present invention.

Referring to FIG. 15A, in the present embodiment, the 3D AND flash memory 1 has a plurality of memory cells 150. In detail, as shown in FIG. 15A, a plurality of gate layers 154 are alternately arranged along the vertical direction, and surround the vertical channel pillars 130 respectively. A portion of the vertical channel pillar 130 surrounded by the gate layer 154 may constitute a memory cell 150. In the present embodiment, a single vertical channel pillar 130 may define three memory cells 150 stacked on each other. However, the present invention is not limited thereto. In other embodiments, the number of memory cells 150 may be adjusted according to the number of gate layers 154 in the stack structure 210. Furthermore, the memory cell 150 may be formed at the intersection of the gate layer 154 and the vertical channel pillar 130. Therefore, the greater the number of vertically stacked gate layers 154, the greater the number of memory cells 150 in the memory string. In addition, although only two vertical channel pillars 130 are illustrated in FIG. 15, the present invention is not limited thereto. In alternative embodiments, the 3D AND flash memory 1 may include a plurality of vertical channel pillars 130, and these vertical channel pillars 130 may be arranged in an array in a top view, as shown in FIG. 1B.

In order to operate the 3D AND flash memory 1, after the 3D AND flash memory 1 is manufactured, conductive lines are formed on the 3D AND flash memory 1 to be electrically connected to the 3D AND flash memory 1. In the present embodiment, as shown in FIG. 15A, some conductive lines are formed above the first S/D pillar 133 as the source to serve as the source lines SL, and other conductive lines are formed above the second S/D pillar 135 as the drain to serve as the bit lines BL, and these source lines SL and bit lines BL are arranged in parallel to each other without contacting each other.

An operation of the memory cell 150 in the 3D AND flash memory 1 will be described below.

As shown in FIG. 15B, for the 3D AND flash memory 1, each memory cell 150 may be operated individually. An operation voltage may be applied to the first S/D pillar 133, the second S/D pillar 135 and the corresponding gate layer 154 (which may be regarded as a gate or a word line) of the memory cell 150 for writing (programming) operation, reading operation or erasing operation. When a writing voltage is applied to the first S/D pillar 133 and the second S/D pillar 135, since the first S/D pillar 133 and the second S/D pillar 135 are connected to the channel layer 134, an electron may be transmitted along a first electrical path E1 and a second electrical path E2 (e.g., a double-sided electrical path) and stored in the entire charge storage structure 132.

In addition, referring to FIG. 15C, in the present embodiment, the memory cells 150 may be arranged in a plurality of columns and a plurality of rows to form a 3D AND flash memory array. Each memory cell 150 may include a gate G electrically connected to the word line WL (i.e., WLm, WLm+1), a source S electrically connected to the source line SL (i.e., SLn, SLn+1), and a drain D electrically connected to the bit line BL (i.e., BLn, BLn+1). It should be noted that in the 3D AND flash memory array of the present embodiment, a plurality of memory cells 150 along the extending direction D1 of the S/D pillars 133 and 135 may be connected in parallel with each other. Specifically, as shown in FIG. 15C, the upper memory cell 150a and the lower memory cell 150b share the same source line SLn+1 and the same bit line BLn+1 through the common S/D pillars 133 and 135, and the gate of the upper memory cell 150a is electrically connected to the upper word line WLm+1, and the gate of the lower memory cell 150b is electrically connected to the lower word line WLm. In this case, the architecture and operation method of the 3D AND flash memory array of the present embodiment are different from those of the conventional 3D NAND flash memory array, wherein the conventional 3D NAND flash memory array includes a plurality of memory cells connected in series.

In summary, in the present embodiment, an additional protective layer with high dielectric is used to cover the surfaces and a sidewall of the uppermost conductive layer to effectively prevent the bridge issue between the source/drain pillar (or conductive plug) and the word line, thereby improving reliability of three-dimensional (3D) memory devices. Further, the forming steps of the barrier structure of the present invention are compatible with the fabrication of current 3D memory device, and can be applied to various 3D memory devices.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A three-dimensional (3D) memory device, comprising:
a dielectric substrate;
a stack structure, disposed on the dielectric substrate, wherein the stack structure includes a plurality of dielectric layers and a plurality of conductive layers stacked alternately; and
a protective layer, continuously covering a top surface, a first sidewall and a bottom surface of an uppermost conductive layer among the plurality of conductive layers, wherein a material of the protective layer includes silicon nitride (SiN).

2. The three-dimensional memory device according to claim 1, further comprising:
a buffer layer, continuously covering a top surface, a first sidewall and a bottom surface of a conductive layer except the uppermost conductive layer among the plurality of conductive layers.

3. The three-dimensional memory device according to claim 2, wherein the buffer layer is further disposed on a portion of the top surface and a portion of the bottom surface of the uppermost conductive layer and is connected to the protective layer.

4. The three-dimensional memory device according to claim 1, further comprising:
a vertical channel pillar, penetrating through the stack structure and adjacent to the first sidewall of the uppermost conductive layer, wherein the protective layer contacts the vertical channel pillar.

5. The three-dimensional memory device according to claim 4, wherein the vertical channel pillar includes:
a first source/drain pillar and a second source/drain pillar, penetrating the stack structure and extending into the dielectric substrate;
a dielectric material, disposed between the first source/drain pillar and the second source/drain pillar to separate the first source/drain pillar and the second source/drain pillar;
a channel layer, surrounding the dielectric material, the first source/drain pillar and the second source/drain pillar, wherein the channel layer is in contact with the first source/drain pillar and the second source/drain pillar; and
a charge storage structure, surrounding the channel layer.

6. The three-dimensional memory device according to claim 5, wherein at least one of the first source/drain pillar and the second source/drain pillar is in contact with the protective layer.

7. The three-dimensional memory device according to claim 6, wherein the uppermost conductive layer is used as a dummy word line.

8. The three-dimensional memory device according to claim 1, the three-dimensional memory device includes a 3D AND flash memory, a 3D NAND flash memory, a 3D NOR flash memory, or a combination thereof.

9. The three-dimensional memory device according to claim 1, wherein a thickness of the protective layer is between 10 Å and 100 Å.

10. The three-dimensional memory device according to claim 2, wherein a thickness of the buffer layer is smaller than a thickness of the protective layer.

11. A method for forming a three-dimensional (3D) memory device, comprising:
forming a stack structure having a plurality of dielectric layers and a plurality of sacrificial layers alternately stacked on the dielectric substrate;
performing a first etching process to form a first opening in the stack structure, wherein the first opening exposes a top surface of the dielectric layer below an uppermost sacrificial layer;
performing a second etching process through the first opening to remove the uppermost sacrificial layer to form a first horizontal opening;
forming a protective layer and a first conductive layer in the first horizontal opening, wherein the protective layer continuously covers a top surface, a first sidewall and a bottom surface of the first conductive layer, wherein a material of the protective layer includes silicon nitride (SiN), and wherein the first opening is adjacent to a second sidewall opposite to the first sidewall of the first conductive layer; and
performing a gate replacement process to replace the plurality of sacrificial layers with a plurality of second conductive layers.

12. The method according to claim 11, wherein before forming the first opening, the method further includes forming a vertical channel pillar in the stack structure, wherein the vertical channel pillar is adjacent to the first sidewall of the first conductive layer, and the protective layer contacts the vertical channel pillar.

13. The method according to claim 12, wherein the vertical channel pillar includes:
a first source/drain pillar and a second source/drain pillar, penetrating the stack structure and extending into the dielectric substrate;
a dielectric material, disposed between the first source/drain pillar and the second source/drain pillar to separate the first source/drain pillar and the second source/drain pillar;
a channel layer, surrounding the dielectric material, the first source/drain pillar and the second source/drain pillar, and wherein the channel layer is in contact with the first source/drain pillar and the second source/drain pillar; and
a charge storage structure, surrounding the channel layer.

14. The method according to claim 13, wherein at least one of the first source/drain pillar and the second source/drain pillar is in contact with the protective layer.

15. The method according to claim 14, wherein the first conductive layer is used as a dummy word line.

16. The method according to claim 11, wherein performing the gate replacement process comprises:
performing a third etching process through the first opening to form a second opening in the stack structure;
performing a fourth etching process through the second opening to remove the sacrificial layer to form a second horizontal opening between the dielectric layers; and
forming the second conductive layers and a buffer layer in the second horizontal opening.

17. The method according to claim 16, wherein after performing the fourth etching process, a sidewall of the protective layer is concave from a sidewall of the dielectric layer and the second sidewall of the first conductive layer to form a gap.

18. The method according to claim 17, wherein the buffer layer is filled in the gap and is connected to the protective layer.

19. The method according to claim 11, wherein a thickness of the protective layer is between 10 Å and 100 Å.

20. The method according to claim 16, wherein a thickness of the buffer layer is smaller than a thickness of the protective layer.
